(19) United States
(12) Patent Application Publication
(10) Pub. No.: US 2014/0326968 A1
(43) Pub. Date: Nov. 6, 2014

(54) IN-CELL OLED TOUCH DISPLAY PANEL STRUCTURE

(71) Applicant: SuperC-Touch Corporation, New Taipei (TW)

(72) Inventor: Hsiang-Yu LEE, New Taipei (TW)

(73) Assignee: SuperC-Touch Corporation, New Taipei (TW)

(21) Appl. No.: 14/267,385

(22) Filed: May 1, 2014

(30) Foreign Application Priority Data
May 3, 2013 (TW) 102208236

(51) Int. Cl. H01L 27/32; G06F 3/041

(52) U.S. Cl. CPC H01L 27/323; G06F 3/0412; G06F 2203/04103
USPC 257/40

(57) ABSTRACT

An in-cell OLED touch display panel structure includes an upper substrate, a lower substrate, a thin film transistor and sensing electrode layer, a cathode layer, and an anode layer. The upper substrate and the lower substrate are parallel to each other and the OLED layer is disposed between the upper and lower substrates. The thin film transistor and sensing electrode layer includes a plurality of gate lines, a plurality of source lines, and a plurality of sensing conductor lines for driving a corresponding pixel driving transistor according to a display pixel signal and a display driving signal. The plurality of sensing conductor lines are disposed corresponding to positions of the plurality of gate lines and the plurality of source lines.

### BACKGROUND OF THE INVENTION

1. Field of the Invention

The present invention relates to a structure of touch display panel and, more particularly, to an in-cell OLED touch display panel structure.

2. Description of Related Art

In recent year, the flat panel display industry has been rapidly developed, and many products have also been made in pursuit of light weight, thinness, small volume and fine image quality for developing several types of flat-panel displays to replace traditional cathode ray tube display (CRT). FIG. 1 schematically illustrates the types of known display panels. As shown in FIG. 1, the flat panel display includes liquid crystal display (LCD), plasma display panel (PDP), organic light emitting diode (OLED) display, field emission display (FED), and vacuum fluorescence display (VFD).

Among these types of flat panel displays, the organic light emitting diode display (OLED) technology is the one with great potential. OLED was first published by Eastman Kodak Co. in 1987. It has the features of thinness, light weight, self-illumination, low driving voltage, high efficiency, high contrast, high color saturation, fast response, flexibility, etc., and is therefore deemed as positively evaluated display technology following the TFT-LCD. In recent years, due to the development of mobile communications, digital products and digital televisions, the demand for high-quality full-color flat-panel displays is rapidly increased. The OLED display is provided with not only the advantages of LCD display including thinness, power-saving, and full-color display, but also the features of wide viewing angle, self-illumination, and fast response that are better than LCD.

FIG. 2 schematically illustrates the basic structure of conventional OLED display. The OLED display 200 includes a cathode layer 210, an OLED layer 220, an anode layer 230, a thin film transistor layer 240, a lower substrate 250, and an upper substrate 260, wherein the OLED layer 220 further includes a hole transporting layer (HTL) 221, an emitting layer 223, and an electron transporting layer (ETL) 225.

The light-emitting principle of OLED is such that the electrons and electric holes are injected from the cathode layer 210 and the anode layer 230 respectively by applying electric field and, after the electric holes pass through the electric hole transport sub-layer 221 and electrons pass through the electron transport sub-layer 225, the electrons and electric holes enter the light-emitting layer 223 with fluorescent characteristics and then are combined to produce excited photons, which immediately release energy and return to the ground state. The released energy will generate different colors of light based on different luminescent materials, so as to cause OLED to emit light.

The conventional OLED display 200 has a cathode layer 260 disposed below the upper substrate 260. The cathode layer 210 can be used to isolate the noise from the top of the upper substrate 260 and receive current of the pixel electrodes of the anode layer 230, so as to control the illumination of light emitting layer 223.

The conventional touch display panel includes a touch panel and a display unit overlapped with the touch panel. The touch panel is configured as an operation interface. The touch panel is transparent so that an image generated by the display unit can be viewed directly by a user without being sheltered by the touch panel. Such well known skill of the touch panel may increase additional weight and thickness of the touch display panel, and may further reduce the light penetration rate, and increase reflectance and haze of the touch display panel.

On-cell and in-cell touch technology are invented to overcome the drawbacks of traditional touch technology described above. The on-cell technology is to dispose a touch sensor on a thin film and then bond the thin film onto the upper side of the upper glass substrate layer. The in-cell touch technology is provided to integrate the touch sensor within the display unit so that the display unit is provided with the ability of the touch panel. Therefore, the touch display panel does not need to be bonded with an additional touch panel so as to simplify the assembly procedure. Such skill is generally developed by display panel manufactures.

For the on-cell touch technology, it needs a sensing layer to be configured on an upper glass substrate or needs to add touch sensing electrodes on the upper substrate, which not only increases the manufacturing cost but also complicates the manufacturing process, and which may also lower the aperture ratio and thus higher the manufacturing cost. Therefore, it desired for the aforementioned OLED touch display panel structure to be improved.

### SUMMARY OF THE INVENTION

The object of the present invention is to provide an in-cell OLED touch display panel structure, which uses in-cell touch technology on OLED display panel and also significantly reduces the material and manufacturing cost, so as to provide the OLED display panel with touch function.

To achieve the object, there is provided an in-cell OLED touch display panel structure, which comprises: an upper substrate, a lower substrate, a thin film transistor and sensing electrode layer, a cathode layer, and an anode layer. The upper substrate and the lower substrate are parallel to each other and the OLED layer is disposed between the upper and lower substrates. The thin film transistor and sensing electrode layer is disposed at one side of the lower substrate facing the OLED layer and includes a plurality of gate lines, a plurality of source lines, and a plurality of sensing conductor lines; according to a display pixel signal and a display driver signal to drive the corresponding pixel driving transistor The cathode layer is disposed at one side of the upper substrate facing the OLED layer. The anode layer is disposed at one side of the thin film transistor and sensing electrode layer facing the OLED layer and includes a plurality of anode pixel electrodes, wherein each of the plurality of anode pixel electrodes is connected to a source or drain of the corresponding pixel driving transistor. The plurality of sensing conductor lines are disposed corresponding to positions of the plurality of gate lines and the plurality of source lines therein.

### BRIEF DESCRIPTION OF THE DRAWINGS

FIG. 1 schematically illustrates the types of conventional display panel;

FIG. 2 schematically illustrates the basic structure of a conventional OLED;

FIG. 3 is a cross sectional view of the in-cell OLED touch display panel structure in accordance with the present invention;

FIG. 4 schematically illustrates the thin film transistor and sensing electrode layer in accordance with the present invention;

FIG. 5(A) is a cross sectional view taking along B-B′ line of FIG. 4 in accordance with an embodiment of the present invention;

FIG. 5(B) is a cross sectional view taking along B-B′ line of FIG. 4 in accordance with another embodiment of the present invention; and

FIG. 6 is a schematic diagram of a plurality of sensing conductor lines in accordance with the present invention.

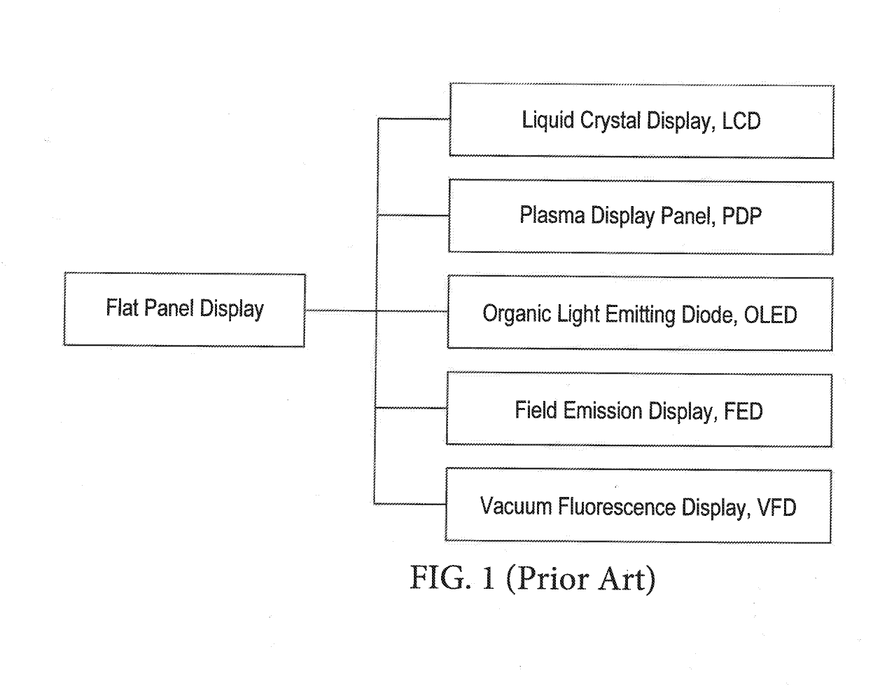

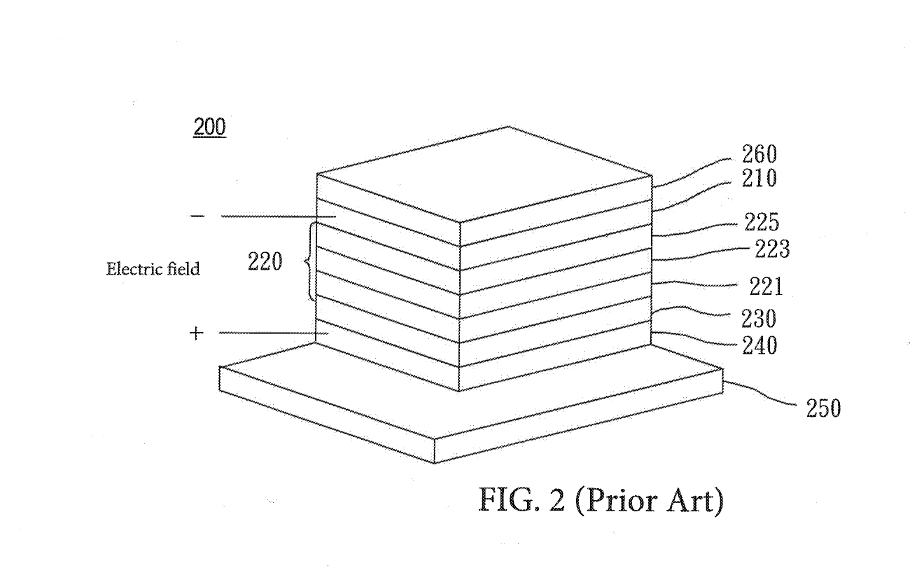

### DETAILED DESCRIPTION OF THE PREFERRED EMBODIMENT

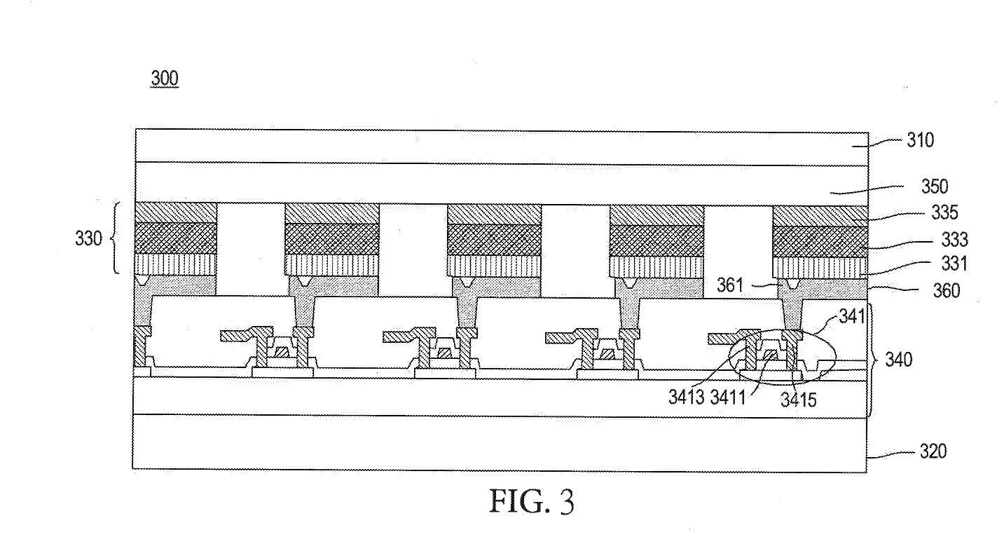

The present invention relates to an in-cell OLED touch display panel structure. FIG. 3 is a cross sectional view of the in-cell OLED touch display panel structure 300 in accordance with the present invention, The in-cell OLED touch display panel structure 300 includes an upper substrate 310, a lower substrate 320, an OLED layer 330, a thin film transistor and sensing electrode layer 340, a cathode layer 350, and an anode layer 360.

The upper substrate 310 and the lower substrate 320 are preferably glass substrates and are parallel to each other. The OLED layer 330 is disposed between the upper and lower substrates 310, 320.

The thin film transistor and sensing electrode layer 340 is disposed at one side of the lower substrate 320 facing the OLED layer 330 and includes a plurality of gate lines (not shown), a plurality of source lines (not shown), a plurality of sensing conductor lines (not shown) and a plurality of pixel driving transistors 341, for driving the corresponding pixel driving transistors 341 according to a display pixel signal and a display driving signal, thereby executing display operation.

The anode layer 360 is disposed at one side of the thin film transistor and sensing electrode layer 340 facing the OLED layer 330 and includes a plurality of anode pixel electrodes 361. Each of the anode pixel electrodes 361 is corresponding to one of the pixel driving transistors 341 of the thin film transistor and sensing electrode layer 340. That is, each of the anode pixel electrodes is connected to a source/drain of the corresponding pixel driving transistor 341, so as to form a pixel electrode of a specific color, for example a red pixel electrode, a green pixel electrode, or a blue pixel electrode.

According to different designs of driving circuit (such as 2T1C is formed with two thin film transistors and a storage capacitor, and 6T2C is formed with six thin film transistors and two storage capacitors), a gate electrode 3411 of at least one thin film transistor in the control circuit is connected to a gate line (not shown). According to different designs of driving circuit, a source/drain 3413 of at least one thin film transistor in the control circuit is connected to a source line (not shown) and a source/drain 3415 of at least one thin film transistor in control circuit is connected to a corresponding anode pixel electrode 361 of the anode layer 360.

The cathode layer 350 is disposed at one side of the upper substrate 310 facing the OLED layer 330 and between the upper substrate 310 and the OLED layer 330. The cathode layer 350 is formed with metal material, preferably metal material with thickness being less than 50 nm. The metal material is selectively to be alloy of aluminum, silver, magnesium, calcium, potassium, lithium, indium, or mixture of lithium fluoride, magnesium fluoride, lithium oxide and aluminum. Due to the thickness of the cathode layer 350 being less than 50 nm, the light generated by the OLED layer 330 can pass through it, so as to show images on the upper substrate 310. The cathode layer 350 is electrically connected in the whole piece, so that it can be used as a shielding. Moreover, the cathode layer 350 also receives the current coming from the anode pixel electrode 361.

In the present invention, a sensing electrode layer is provided on the conventional thin film transistor layer on which a sensing touch pattern structure is defined, so as to form the thin film transistor and sensing electrode layer 340 in accordance with the present invention. Therefore, there is no need to arrange a sensing electrode layer on the upper glass substrate or the lower glass substrate of a display panel, so as to reduce the manufacturing cost, simplify the manufacturing process and increase the yield rate. The thin film transistor and sensing electrode layer 340 is disposed at one side of the lower substrate 320 that faces the OLED layer 330.

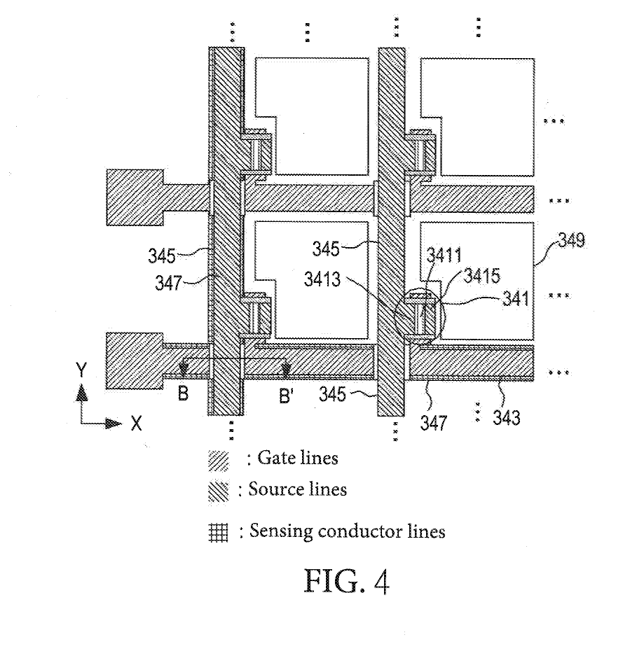

FIG. 4 schematically illustrates the thin film transistor and sensing electrode layer 340 in accordance with the present invention, which is viewed from the upper substrate 310 to the lower substrate 320. The thin film transistor and sensing electrode layer 340 includes a plurality of gate lines 343, a plurality of source lines 345, a plurality of sensing conductor lines 347, a plurality of transistors 341 (each pixel electrode may be controlled by more than one transistors according to different driving circuits, and nominally one transistor is shown for illustrative purpose only), and a plurality of pixel regions 349. As the conventional thin film transistor being formed with a sensing layer, the gate lines 343 and the source lines 345 of the thin film transistor and sensing electrode layer 340 are arranged in a first direction (X-direction) and a second direction (Y-direction), respectively, so as to present a matrix arrangement by intersecting the gate lines 343 and the source lines 345, wherein the first direction is substantially vertical with the second direction. The line width of the sensing conductor line 347 is preferably greater than or equal to the line width of the source line 345 or the line width of the gate line 343.

As shown in FIG. 4, the plurality of sensing conductor lines 347 are disposed at positions corresponding to the positions of the plurality of gate lines 343 and the plurality of source lines 345, and the plurality of sensing conductor lines 347 are disposed at one side of the plurality of gate lines 343 and the plurality of source lines 345 opposite to the OLED layer 330.

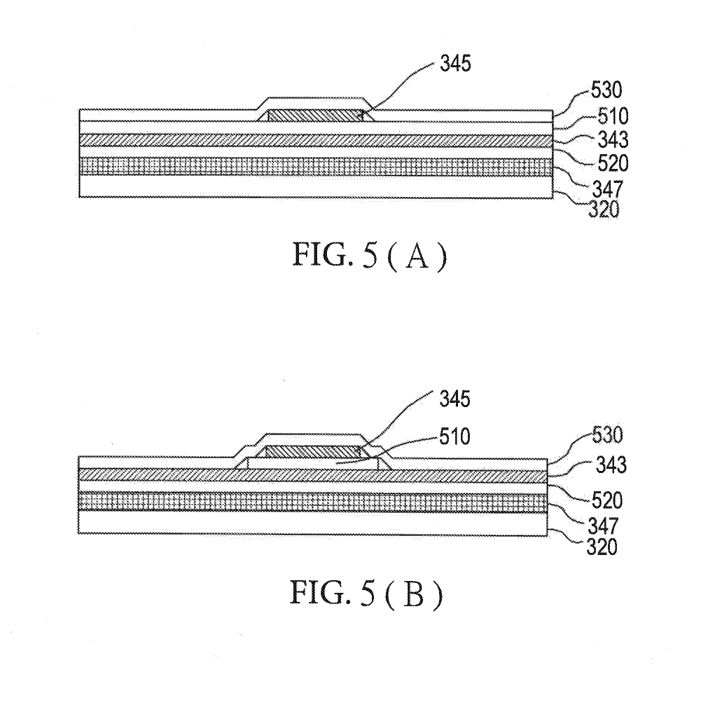

FIG. 5(A) is a cross sectional view taking along B-B′ line of FIG. 4 in accordance with an embodiment of the present invention. As shown in FIG. 5(A), the gate line 343 is arranged on the lower substrate 320 and there is a first insulation region 510 arranged above the gate line 343 so that the source line 345 and the gate line 343 are insulated from each other. There is a second insulation region 520 arranged below the gate line 343 so that the sensing conductor line 347 and the gate line 343 are insulated from each other. Further, there is a third insulation region 530 arranged above the source line 345. FIG. 5(B) is a cross sectional view taking along B-B′ line of FIG. 4 in accordance with another embodiment of the present invention. The arrangement in FIG. 5(B) is similar to that in FIG. 5(A), except that the first insulation region 510 is provided for allowing the source line 345 and the gate line 343 to be insulated from each other, so that the first insulation region 510 is arranged only at an intersection of the source line 345 and the gate line 343.

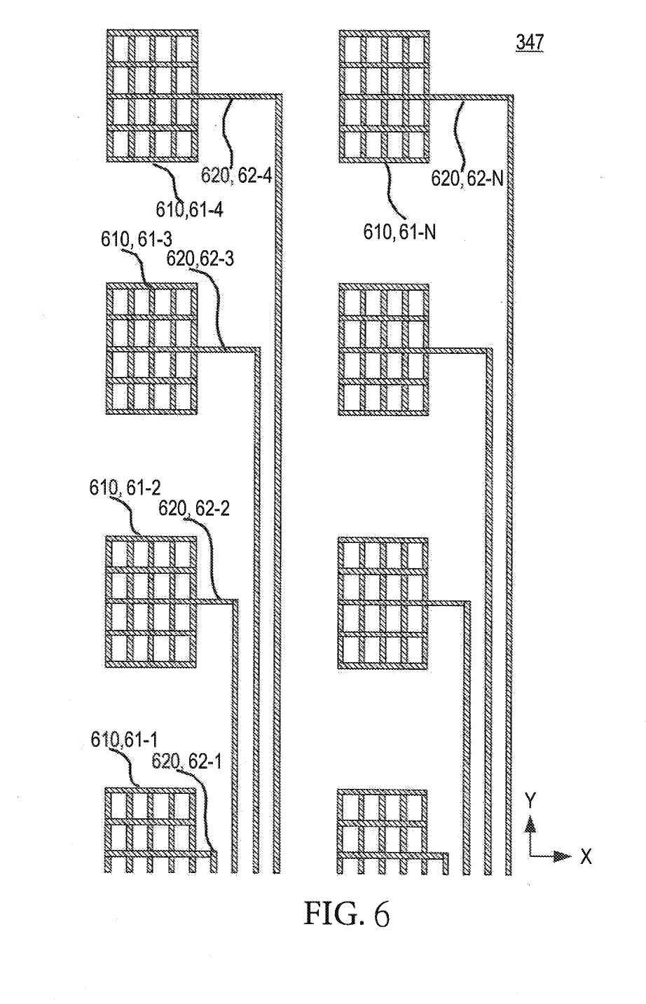

FIG. 6 is a schematic diagram of the plurality of sensing conductor lines in accordance with the present invention, which is viewed from the lower substrate 320 to the upper substrate 310. As shown in FIG. 6, the sensing conductor lines 610, 620 of the thin film transistor and sensing electrode layer 340 are arranged in a first direction (X-direction) and a second direction (Y-direction), respectively, wherein the first direction is substantially vertical with the second direction. The sensing conductor lines 610, 620 of the thin film transistor and sensing electrode layer 340 are made of conductive metal material or alloy material, wherein the conductive metal material is selectively to be chromium, barium, aluminum, titanium, and alloy thereof.

The sensing conductor lines 610, 620 are divided into a first group of sensing conductor lines 610 and a. second group of sensing conductor lines 620. The first group of sensing conductor lines 610 is formed with N quadrilateral regions 61-1 to 61-N, where N is a positive integer. The sensing conductor lines in any one of the quadrilateral regions are electrically connected together while the sensing conductor lines in any two quadrilateral regions are not electrically connected, so as to form a single-layered touch pattern on the thin film transistor and sensing electrode layer 340. Each of the quadrilateral regions 61-1 to 61-N is formed in a rectangle, square, or rhombus shape. In this embodiment, each of the quadrilateral regions 61-1 to 61-N is formed in a rectangle shape, wherein the plurality of sensing conductor lines are disposed at positions corresponding to the positions of the plurality of source lines 345 and the plurality of gate lines 343.

The second group of sensing conductor lines 620 is formed with N conductor traces 62-1 to 62-N, wherein each of the N conductor traces is electrically connected to a corresponding quadrilateral region 61-1 to 61-N while any two conductor traces 62-1 to 62-N are not electrically connected.

The first group of sensing conductor lines 610 is correspondingly connected to the second group of sensing conductor lines 620. Therefore, the first group of sensing conductor lines 610 can form a single-layered touch pattern on the thin film transistor and sensing electrode layer 340. The line width of the first group of sensing conductor lines 610 or the second group of sensing conductor lines 620 is preferably greater than or equal to the line width of the source line 345 or the gate line 343.

The OLED layer 330 includes a hole transporting layer 331, an emitting layer 333, and an electron transporting layer 335.

In view of the foregoing, it is known that the present invention is capable of forming a single-layered touch pattern on the thin film transistor and sensing electrode layer 340, which has the advantage of not requiring to arrange a sensing electrode layer on the upper glass substrate or lower glass substrate of the LCD panel, thereby lowering the cost and decreasing the number of manufacturing steps.

Although the present invention has been explained in relation to its preferred embodiment, it is to be understood that many other possible modifications and variations can be made without departing from the spirit and scope of the invention as hereinafter claimed.

What is claimed is:

1. An in-cell OLED touch display panel structure, comprising:
an upper substrate;
a lower substrate parallel to the upper substrate;
an OLED layer configured between the upper substrate and the lower substrate;
a thin film transistor and sensing electrode layer disposed at one side of the lower substrate facing the OLED layer, the thin film transistor and sensing electrode layer including a plurality of gate lines, a plurality of source lines, and a plurality of sensing conductor lines for driving a corresponding pixel driving transistor according to a display pixel signal and a display driving signal;
a cathode layer disposed at one side of the upper substrate facing the OLED layer; and
an anode layer disposed at one side of the thin film transistor and sensing electrode layer facing the OLED layer, the anode layer including a plurality of anode pixel electrodes, each of the plurality of anode pixel electrodes being connected to a source or drain of the corresponding pixel driving transistor,
wherein the plurality of sensing conductor lines are disposed corresponding to positions of the plurality of gate lines and the plurality of source lines.

2. The in-cell OLED touch display panel structure as claimed in claim 1, wherein the plurality of sensing conductor lines are disposed at one side of the plurality of gate lines and the plurality of source lines opposite to the OLED layer.

3. The in-cell OLED touch display panel structure as claimed in claim 2, wherein the plurality of sensing conductor lines are divided into a first group of sensing conductor lines and a, second group of sensing conductor lines, the first group of sensing conductor lines being formed with N quadrilateral regions, where N is a positive integer, the sensing conductor lines in any one of the quadrilateral regions being electrically connected together while the sensing conductor lines in any two quadrilateral regions are not electrically connected, so as to form a single-layered touch pattern on the thin film transistor and sensing electrode layer.

4. The in-cell OLED touch display panel structure as claimed in claim 3, wherein the second group of sensing conductor lines is formed with N conductive traces, each of the N conductive traces being electrically connected to a corresponding quadrilateral region, while any two conductive traces are not electrically connected.

5. The in-cell OLED touch display panel structure as claimed in claim 4, wherein the plurality of sensing conductor lines of the thin film transistor and sensing electrode layer are arranged in a first direction and a second direction.

6. The in-cell OLED touch display panel structure as claimed in claim 5, wherein the first direction is vertical with the second direction.

7. The in-cell OLED touch display panel structure as claimed in claim 6, wherein each of the quadrilateral regions is formed in a rectangle, square, or rhombus shape.

8. The in-cell OLED touch display panel structure as claimed in claim 7, wherein the plurality of sensing conductor lines of the thin film transistor and sensing electrode layer are made of conductive metal material or alloy material.

9. The in-cell OLED touch display panel structure as claimed in claim 8, wherein the conductive metal material is selectively to be chromium, barium, aluminum, titanium, and alloy thereof.

10. The in-cell OLED touch display panel structure as claimed in claim 1, wherein the cathode layer is formed with metal material.

11. The in-cell OLED touch display panel structure as claimed in claim 10, wherein the metal material is selectively to be alloy of aluminum, silver, magnesium, calcium, potassium, lithium, indium, or mixture of lithium fluoride, magnesium fluoride, lithium oxide and aluminum.

12. The in-cell OLED touch display panel structure as claimed in claim 11, wherein the OLED layer includes a hole transporting layer, an emitting layer, and an electron transporting layer.
